(19) United States
(12) Patent Application Publication
(10) Pub. No.: US 2025/0385677 A1
(43) Pub. Date: Dec. 18, 2025

(54) SWING REGULATION TECHNIQUE TO IMPROVE LINE DRIVER PERFORMANCE

(71) Applicant: Analog Devices International Unlimited Company, Limerick (IE)

(72) Inventors: Rajasekhar Nagulapalli, Northampton (GB); Chetan Kurade, Colorado Springs, CO (US)

(21) Appl. No.: 19/228,424

(22) Filed: Jun. 4, 2025

Related U.S. Application Data
(60) Provisional application No. 63/659,297, filed on Jun. 12, 2024.

(51) Int. Cl. H03K 19/0185; H03K 17/22; H03K 19/0948

(52) U.S. Cl. CPC H03K 19/018528; H03K 17/223; H03K 19/0948

(57) ABSTRACT

Techniques are described for swing regulation to improve line driver performance of a transmitter. Such a system may comprise a voltage mode logic (VML) driver, a boost circuit, and a bias circuit for swing constant with respect to supply voltage variations. The bias circuit outputs one or more bias currents to the boost circuit, which feeds one or more boosting currents to the VML driver such that the VML driver outputs a driver output to drive a resistive load, e.g., a coaxial cable, with a swing of the driver output being constant. Simulations show that a VML driver incorporated with a boost circuit and a bias circuit is approximately constant, e.g., having only 40 mV sensitivity over 300 mV supply variation.

### CLAIM OF PRIORITY

This application claims the benefit of priority to U.S. Provisional Application Ser. No. 63/659,297, titled “SWING REGULATION TECHNIQUE TO IMPROVE LINE DRIVER PERFORMANCE” to Rajasekhar Nagulapalli et al., filed Jun. 12, 2024, which is incorporated by reference herein in its entirety.

### FIELD OF THE DISCLOSURE

This document pertains generally, but not by way of limitation, to transmitters for wireline communication applications.

### BACKGROUND

Wireline communication systems are widely employed in high-speed data transfer applications, including computer interconnects, backplanes, and chip-to-chip interfaces. These systems utilize physical conductors—such as copper traces or cables—to transmit electrical signals between a transmitter and a receiver. To maintain signal integrity and meet stringent performance demands, wireline transmitters drive signals across transmission lines with well-controlled voltage levels, rise and fall times, and impedance characteristics. The design of the transmitter, particularly its output driver, plays an important role in ensuring signal fidelity, power efficiency, and compatibility with receiver thresholds.

Two common driver architectures used in wireline transmitters are current mode logic (CML) and voltage mode logic (VML). In a CML driver, a constant tail current is steered through differential branches of a switching network, producing a differential output voltage across load resistors. CML drivers are desirable due to their high-speed operation, reduced output voltage swing, and inherently low common-mode noise. In contrast, VML drivers use voltage switching to control the output state, typically using CMOS transistors to drive the output nodes between defined supply levels. VML architectures may offer lower power consumption and better integration with digital logic but may suffer from increased switching noise and slower edge rates. The choice between CML and VML depends on system requirements such as data rate, power budget, and noise tolerance.

### SUMMARY OF THE DISCLOSURE

This disclosure describes various techniques for swing regulation to improve line driver performance of a transmitter. Such a system may include a voltage mode logic (VML) driver, a boost circuit, and a bias circuit for swing constant with respect to supply voltage variations. The bias circuit outputs one or more bias currents to the boost circuit, which feeds one or more boosting currents to the VML driver such that the VML driver outputs a driver output to drive a resistive load, e.g., a coaxial cable, with a swing of the driver output being constant.

In some aspects, this disclosure is directed to a system for swing regulation, comprising: a bias circuit configured for outputting one or more bias currents; a boost circuit configured for receiving the one or more bias currents and generating one or more boosting currents; and a voltage mode logic (VML) driver powered by a source voltage, the VML driver configured for receiving the one or more boosting currents and outputting a driver output to drive a load with a swing of the driver output being approximately constant.

In some aspects, this disclosure is directed to a method for applying current biasing for constant swing in a voltage mode logic (VML) driver, the method comprising: outputting one or more bias currents to a boost circuit; supplying one or more boosting currents to a VML driver; and outputting a driver output to drive a resistive load with a swing of the driver output being approximately constant.

In some aspects, this disclosure is directed to a system for regulating voltage mode logic (VML) driver swing, comprising: a bias circuit including: a first bias branch formed by a first bias circuit switch and a biasing terminal resistor, a first operational amplifier having a positive input receiving a voltage that is half of a source voltage, and a negative input connected to an output of the first operational amplifier, and a second operational amplifier having a positive input coupled to the output of the first operational amplifier, a negative input coupled to a reference voltage, and an output coupled to a gate of the first bias circuit switch; a boost circuit comprising parallel boost branches configured to receive bias currents from the bias circuit and generate boosting currents; and a VML driver configured to receive the boosting currents and output a driver signal having an approximately constant swing relative to variations in the source voltage.

### BRIEF DESCRIPTION OF THE DRAWINGS

In the drawings, which are not necessarily drawn to scale, like numerals may describe similar components in different views. The drawings illustrate generally, by way of example, but not by way of limitation, various embodiments discussed in the present document.

FIG. 1 depicts a conventional CML driver with a 500 reference load.

FIG. 2 depicts a conventional VML driver.

FIG. 3 depicts a swing-boosted VML driver according to one or more embodiments of this disclosure.

FIG. 4 depicts a system block diagram of a VML driver, a boost circuit, and a bias circuit for swing constant with respect to supply voltage variations according to one or more embodiments of this disclosure.

FIG. 5 depicts a circuit diagram of a bias circuit according to one or more embodiments of this disclosure.

FIG. 6 depicts a comparison of swing under supply voltage variations between approaches without a biasing circuit and with a biasing circuit according to one or more embodiments of this disclosure.

FIGS. 7A and 7B depict eye diagrams with boosted current sources for 800 mV and 1200 mV swing, respectively, according to one or more embodiments of this disclosure.

FIG. 8 is a flow diagram of applying current biasing for constant swing in a VML driver according to one or more embodiments of this disclosure.

### DETAILED DESCRIPTION

For a transmitter (TX) used in wireline communication applications, a TX output line driver plays an important role in TX performance and power consumption. There are two potential architectures for the driver: current mode logic (CML) and voltage mode logic (VML). The present inventors have recognized that the CML driver is not power efficient and that the swing of a VML driver is limited by the supply, as described below. In many cases, the supply is limited to under 1V supply (driven by reliability concern), which is a big disadvantage while targeting for higher loss channel. Various efforts have been taken to address this limitation by injecting current into the termination resistance. The present inventors have recognized a need for techniques for swing regulation to improve line driver performance.

This disclosure is directed to techniques for regulating voltage mode logic (VML) driver swing in wireline communication systems. Specifically, the disclosure describes techniques for maintaining constant output swing despite supply voltage variations by using a bias circuit to output bias currents to a boost circuit, which generates boosting currents for a VML driver. The bias circuit adjusts the bias currents to track negatively with changes in the source voltage, allowing the VML driver to maintain approximately constant swing while driving a resistive load, with sensitivity of only 40 mV over 300 m V of supply variation.

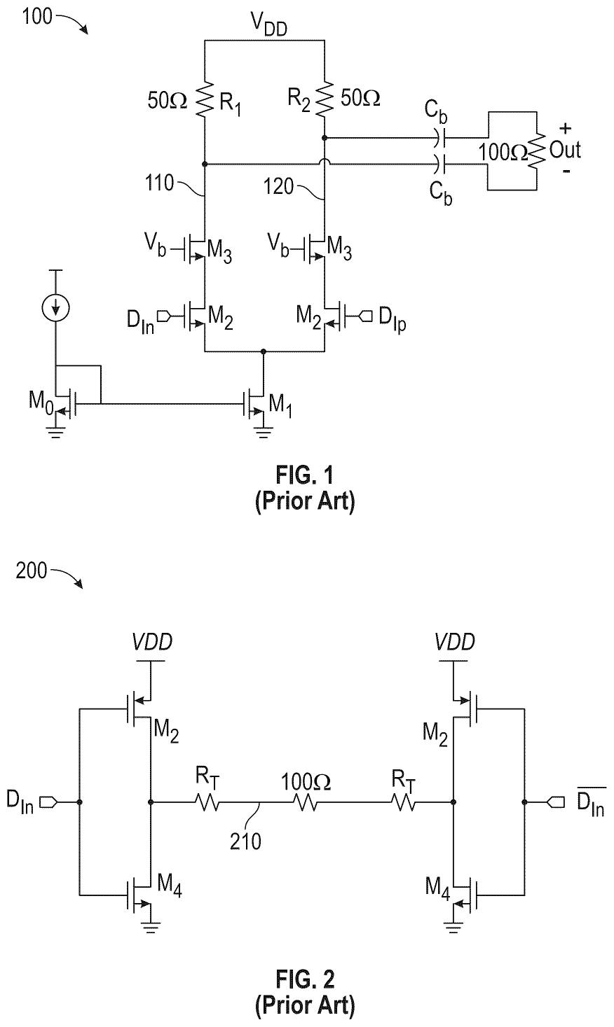

FIG. 1 depicts a schematic of a typical CML driver 100, which has a differential pair of circuit branches 110/120 with known bias currents such that the CML driver switches current under a 50Ω operation load. The CML driver mainly works based on the current steering principle. The output swing may be expressed as follows:

$${V}_{pk - pk} = 50 * {I}_{B} \qquad ( 1 )$$

Unfortunately, the bias current of the CML driver is divided between the near-end and far-end termination. As a result, only half of the current will reach the load. Therefore, the CML driver is not power efficient.

A VML driver is a potential solution to improve power efficiency by keeping the far end and near end termination in series and the output's peak-to-peak (pk-pk) differential swing equal to the V_{DD}. An example of a VML driver is shown in FIG. 2.

FIG. 2 shows a conventional VML driver schematic 200. The VML driver comprises multiple switches M₂/M₄, forming a bridge circuit, with each bridge branch having a pair of switches M₂ and M₄, e.g., transistors such as field-effect transistors. The VML driver has a bridge output to drive a load via a termination resistance (R_{T}). The switches M₂ and M₄ are sized such that a series combination of the resistor R_{T} and the switches M₂/M₄ forms the 50Ω termination resistance. When the pin Din (for data input) is high, the switch M₄ is biased in the triode region, and current flows from the supply to M₄ and then the output channel. The current may be expressed as follows:

$${I}_{bias} = {V}_{DD} / 200 \qquad ( 2 )$$

The equation reveals that as long as the supply voltage V_{DD} and the peak-peak swing are approximately the same, the current consumed by the VML driver is only 25% of the CML driver.

The main disadvantage of a VML driver, such as the VML driver 200 shown in FIG. 2, is that the swing limited by the supply. In most cases, the supply is limited to under 1V supply (driven by reliability concerns), which may be a big disadvantage while targeting a higher loss channel.

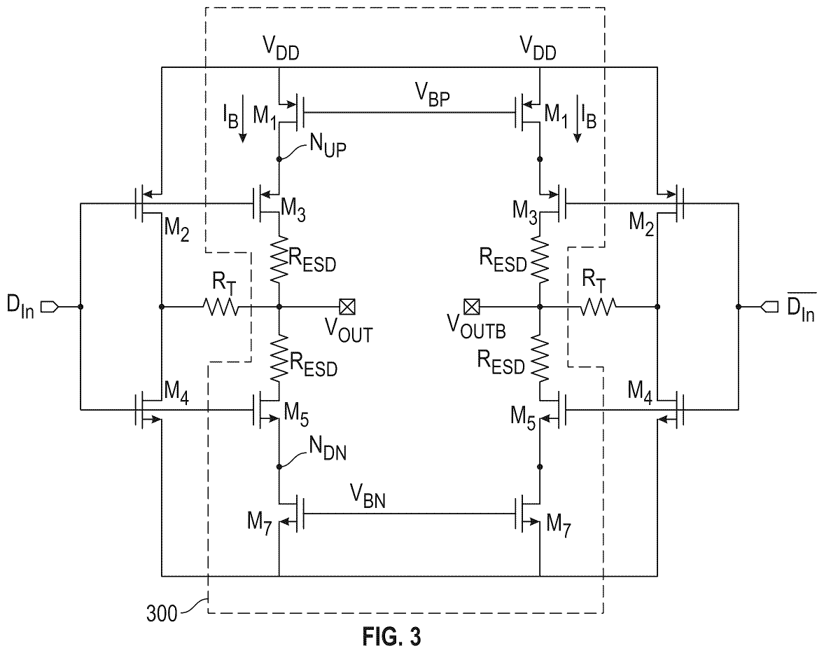

FIG. 3 depicts a swing-boosted VML driver according to one or more embodiments of this disclosure. The swing-boosted VML driver comprises a VML driver and a boost circuit 300 coupled to the VML driver for current boosting. As shown in FIG. 3, the VML driver comprises two parallel driver branches, with each driver branch formed by switches M₂ and M₄ (also referred to as driver switches hereinafter) connected in series and a resistor R_{T} having one end coupled in between M₂ and M₄ and another end for voltage output (V_{OUT}), similar to the VML driver 200 shown in FIG. 2. The resistor R_{T} functions as a partial termination resistance, contributing a majority of the resistance.

The boost circuit 300 comprises a pair of boost branches in parallel to each boost branch having switches M₁, M₃, M₅, and M₇ coupled in series. Specifically, switches M₁ and M₇ function as current sources. Switches M₃ and M₅ act as synchronization switches to decide which current sources to be on. If the Din terminal is high, the voltage at node Vₒᵤₜ and node V_{outb} may be expressed respectively as in equation (3) and equation (4), which show V_{outb} is boosted by 25 I_{B}, where I_{B} is the boosting current. A single-ended pk-pk swing is boosted by 50 I_{B} and differential swing is boosted by 100 I_{B}. A total swing may be expressed as equation (5).

$${V}_{out} = \frac{3}{4} {V}_{DD} + 25 {I}_{B} \qquad ( 3 )$$

$${V}_{outb} = \frac{1}{4} {V}_{DD} + 25 {I}_{B} \qquad ( 4 )$$

$${V}_{sw} = {V}_{DD} + 100 {I}_{B} \qquad ( 5 )$$

Sometimes, it is desirable to shield all transistors exposed to external bump, e.g., the switch M₃ needs a protection resistor. In one or more embodiments, a pair of protection resistors R_{ESD} may be incorporated in series on each boost branch to protect switches M₃ and M₅. The maximum achievable swing with this technique may be expressed as 2 V_{DD}-200 mV, with an assumption of 100 m V headroom for each current source (M₁ or M₇). One main disadvantage of such a swing-boosted VML driver is that the swing is a function of supply voltage (V_{DD}). Therefore, the swing changes when the supply varies.

One way to implement a V_{DD}-insensitive VML driver is to modulate the boosting current in such a way that it may keep the VML driver swing approximately constant. In some embodiments, the boosting current may track negatively with the supply voltage. In one or more embodiments, the boosting current I_{B} may be expressed as follows:

$${I}_{B} = ( swing - {V}_{DD} ) / 100 \qquad ( 6 )$$

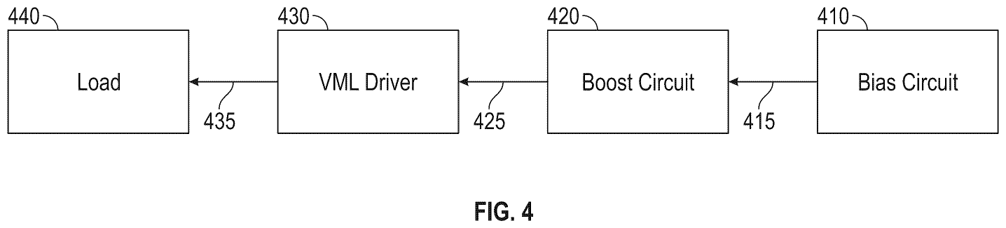

FIG. 4 depicts a system block diagram of a VML driver, a boost circuit, and a bias circuit for swing constant with respect to supply voltage variations according to one or more embodiments of this disclosure. A bias circuit 410 outputs one or more bias currents 415 to a boost circuit 420, which feeds one or more boosting currents 425 to the VML driver 430 such that the VML driver 430 outputs a driver output 435 to drive a 50-ohm resistive load 440, e.g., a coaxial cable, with a swing of the driver output being approximately constant.

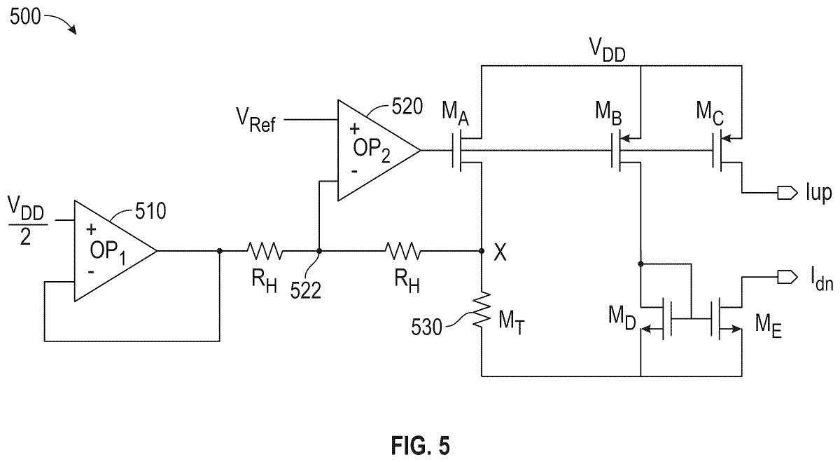

FIG. 5 depicts a circuit diagram of a bias circuit according to one or more embodiments of this disclosure. The bias circuit 500 comprises a first operational amplifier (OP₁) 510, a second operational amplifier (OP₂) 520, and a plurality of bias circuit switches MA through ME. Specifically, the switches M_{A}, M_{B}, and Mc may be p-channel metal-oxide-semiconductor field-effect transistor (PMOS) switches having their source terminals coupled to a source voltage V_{DD} and their gate terminals coupled to an output of the operational amplifier OP₂ 520. Switches M_{D} and M_{E} may be n-channel metal-oxide-semiconductor field-effect transistor (NMOS) switches, with their source terminals coupled together and their gate terminals connected together to the drain terminal of the switch M_{D}. The PMOS switch M_{A} and a biasing terminal resistor R_{T} 530 (which has the same resistance as the terminal resistor R_{T} shown in FIG. 2) form a first bias branch; the switches M_{B} and M_{D} form a second bias branch. The switches Mc and ME (also referred to as a first bias output switch and a second bias output switch) have their drain terminals outputting a first bias current (Iᵤₚ) and a second bias current (I_{dn}), respectively. The bias currents Iᵤₚ and Ian are fed respectively into nodes N_{UP} and N_{DN} of the boost circuit 300 shown in FIG. 3 for enhancement of the boosting current I_{B}. The node Nᵤₚ is between the switch M₁ and the switch M₃; the node N_{dn} is between the switch M₅ and the switch M₇.

As shown in FIG. 5, the operational amplifier OP1 510 has an non-inverting input receiving a voltage that is half of the source voltage V_{DD} and an inverting input connected to an OP1 output 512, which couples to node x (a node between the switch M_{A} and the resistor 530) via a pair of series resistors R_{H}. The operational amplifier OP2 520 has a non-inverting input coupled to a node 522 between the resistors R_{H}, an inverting input receiving a reference voltage V_{Ref}, and an OP2 output coupled to gate terminals of the switches M_{A}, M_{B}, and M_{C}.

In operation, the operational amplifier OP2 520 adjusts the voltage of node x such that the voltage of the node x and the current through the switch M_{A} are increasing with a decrease in the supply voltage, and may be expressed as:

$${V}_{x} = 2 {V}_{ref} - \frac{{V}_{DD}}{2} \qquad ( 7 )$$

$${I}_{M 1} = ( 2 {V}_{ref} - \frac{{V}_{DD}}{2} ) / {R}_{T} \qquad ( 8 )$$

In conventional VML drivers, swing adjustment may be difficult because the swing depends on the supply voltage V_{DD}. In embodiments of the present disclosure, fine control of the swing may be achieved by controlling the reference voltage. For a given swing, the VML circuit incorporated with the boost circuit and the bias circuit may extract the maximum possible swing out of the VML structure and the rest of the swing from current boosting. Therefore, such a VML circuit may partition the swing out of these two sections.

For example, if the supply voltage is 800 mV and a swing of 1 V is required, the VML driver supplies 800 mV; the boosting circuit and the bias circuit together contribute the remaining 200 mV. If the supply voltage drops to 750 mV for any reason, the boosting circuit and the bias circuit automatically increase the swing by 250 m V to keep the total swing approximately constant.

Various working circuits have been designed and simulated with a targeted 1.2 V pk-pk differential swing.

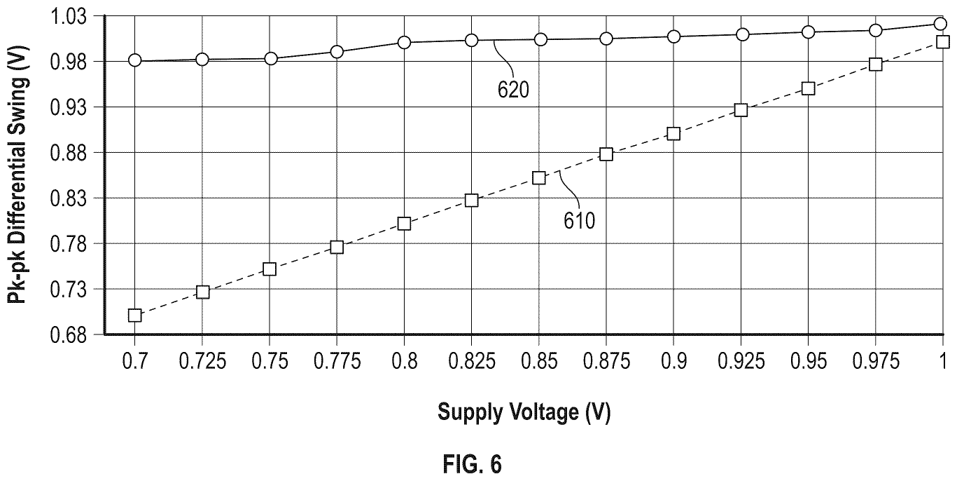

FIG. 6 depicts a comparison of swing under supply voltage variations between approaches without a bias circuit and with a bias circuit according to one or more embodiments of this disclosure. The x-axis represents the supply voltage in volts and the y-axis represents the peak-to-peak differential swing in volts. As shown in FIG. 6, the swing 610 due to the VML driver alone is proportional to the supply as expected, while the swing 620 for a VML driver incorporated with a boost circuit and a bias circuit is approximately constant, having only 40 mV sensitivity over 300 mV supply variations.

The VML driver incorporated with a boost circuit and a bias circuit may also be very insensitive to an offset of operational amplifiers as long as they are independent of the supply voltage.

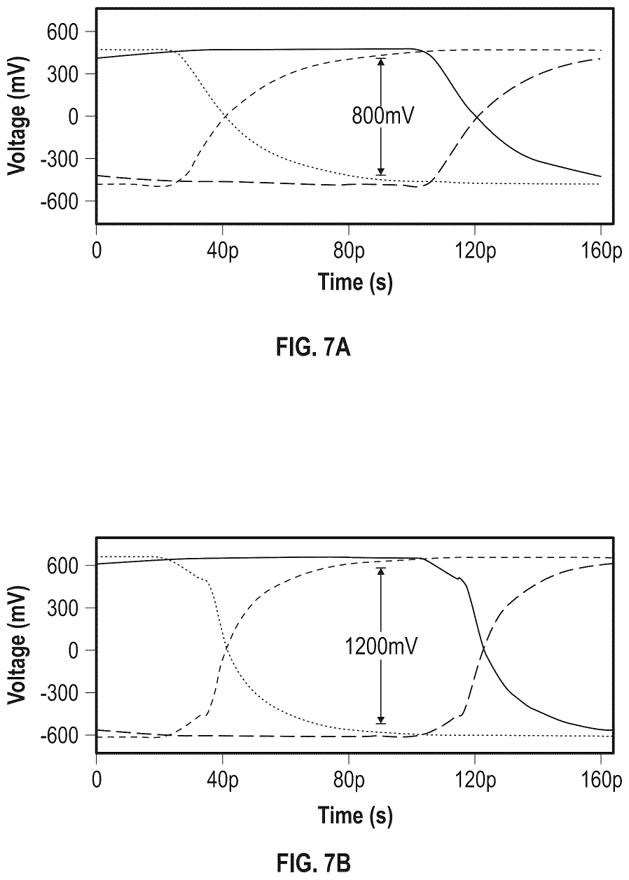

FIGS. 7A and 7B depict eye diagrams with a boosted current source for 800 mV and 1200 mV swing, respectively, according to one or more embodiments of this disclosure. In both FIGS. 7A and 7B, the x-axis represents time in seconds and the y-axis represents voltage in millivolts. Again, the overall swings are approximately constant over time for source voltages of 800 m V and 1200 mV in FIGS. 7A and 7B, respectively.

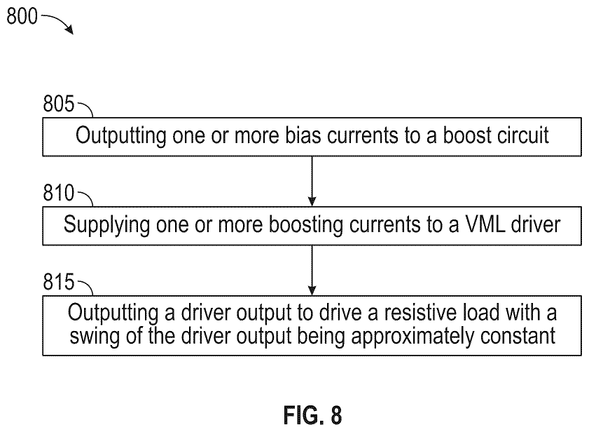

FIG. 8 is a flow diagram of an example of a method 800 of applying current biasing for approximately constant swing in a VML driver according to one or more embodiments of this disclosure. At block 805, a bias circuit outputs one or more bias currents to a boost circuit. At block 810, the boost circuit supplies or feeds one or more boosting currents to a VML driver. At block 815, the VML driver outputs a driver output to drive a resistive load with a swing of the driver output being approximately constant.

Various examples of the disclosure are described as follows.

Example 1 is a system for swing regulation, comprising: a bias circuit configured for outputting one or more bias currents; a boost circuit configured for receiving the one or more bias currents and generating one or more boosting currents; and a voltage mode logic (VML) driver powered by a source voltage, the VML driver configured for receiving the one or more boosting currents and outputting a driver output to drive a load with a swing of the driver output being approximately constant.

In Example 2, the subject matter of Example 1 includes, wherein the bias circuit comprises: a first bias branch formed by a first bias circuit switch and a biasing terminal resistor; a first operational amplifier (OP1) that has a positive input receiving a voltage that is half of the source voltage and a negative input connected to an OP1 output, the OP1 output coupled to a node in the first bias branch via two series resistors; a second operational amplifier (OP2) that has a positive input coupled to the OP1 output via one of the two series resistors, a negative input coupled to a reference voltage, and an OP2 output coupled to a gate of the first bias circuit switch; a first bias output switch that has a source terminal coupled to the source voltage, a gate terminal coupled to the OP2 output, and a drain terminal outputting a first bias current; and a second bias output switch that has a source terminal coupled to the biasing terminal resistor and a drain terminal outputting a second bias current.

In Example 3, the subject matter of Example 2 includes, wherein the bias circuit further comprises: a second bias branch in parallel to the first bias branch, the second bias branch comprises a second bias circuit switch and a third bias circuit switch, the second bias circuit switch has a source terminal connected to the source voltage and a gate terminal coupled to the OP2 output.

In Example 4, the subject matter of Examples 2-3 includes, wherein the VML driver comprises multiple switches forming a bridge circuit with each bridge branch having a pair of switches, the VML driver has a bridge output to drive the load via a termination resistance, the termination resistance has a resistance value same as the biasing terminal resistor.

In Example 5, the subject matter of Examples 1˜4 includes, wherein the load is a resistive load.

In Example 6, the subject matter of Examples 1-5 includes, wherein the bias circuit is configured to adjust the one or more bias currents to track negatively with changes in the source voltage.

In Example 7, the subject matter of Examples 1-6 includes, wherein the boost circuit comprises: a pair of boost branches connected in parallel, each boost branch comprising: a first switch functioning as a current source; a second switch functioning as a synchronization switch; a third switch functioning as a synchronization switch; and a fourth switch functioning as a current source.

In Example 8, the subject matter of Example 7 includes, protection resistors connected in series within each boost branch to protect the synchronization switches.

In Example 9, the subject matter of Examples 1-8 includes, wherein the one or more bias currents comprise: a first bias current (Iup) connected to a first node between switches in a first boost branch of the boost circuit; and a second bias current (Idn) connected to a second node between switches in a second boost branch of the boost circuit.

In Example 10, the subject matter of Examples 1-9 includes, wherein the VML driver and boost circuit are configured to: extract a first portion of the swing from the VML driver up to the source voltage level; and generate a remaining portion of the swing through current boosting.

Example 11 is a method for applying current biasing for constant swing in a voltage mode logic (VML) driver, the method comprising: outputting one or more bias currents to a boost circuit; supplying one or more boosting currents to a VML driver; and outputting a driver output to drive a resistive load with a swing of the driver output being approximately constant.

In Example 12, the subject matter of Example 11 includes, wherein outputting one or more bias currents comprises: adjusting the one or more bias currents to track negatively with changes in a source voltage powering the VML driver.

In Example 13, the subject matter of Examples 11-12 includes, wherein supplying one or more boosting currents comprises: generating the one or more boosting currents through a pair of parallel boost branches, each boost branch including synchronization switches and current source switches.

In Example 14, the subject matter of Example 13 includes, protecting the synchronization switches using protection resistors connected in series within each boost branch.

In Example 15, the subject matter of Examples 11-14 includes, controlling a reference voltage to achieve control of the swing of the driver output.

In Example 16, the subject matter of Examples 11-15 includes, extracting a first portion of the swing from the VML driver up to a source voltage level; and generating a remaining portion of the swing through current boosting.

In Example 17, the subject matter of Examples 11-16 includes, wherein outputting one or more bias currents comprises: supplying a first bias current to a first node between switches in a first boost branch; and supplying a second bias current to a second node between switches in a second boost branch.

Example 18 is a system for regulating voltage mode logic (VML) driver swing, comprising: a bias circuit including: a first bias branch formed by a first bias circuit switch and a biasing terminal resistor, a first operational amplifier having a positive input receiving a voltage that is half of a source voltage, and a negative input connected to an output of the first operational amplifier, and a second operational amplifier having a positive input coupled to the output of the first operational amplifier, a negative input coupled to a reference voltage, and an output coupled to a gate of the first bias circuit switch; a boost circuit comprising parallel boost branches configured to receive bias currents from the bias circuit and generate boosting currents; and a VML driver configured to receive the boosting currents and output a driver signal having an approximately constant swing relative to variations in the source voltage.

In Example 19, the subject matter of Example 18 includes, wherein the bias circuit further comprises: a first bias output switch having a source terminal coupled to the source voltage, a gate terminal coupled to the output of the second operational amplifier, and a drain terminal outputting a first bias current; and a second bias output switch having a source terminal coupled to the biasing terminal resistor and a drain terminal outputting a second bias current.

In Example 20, the subject matter of Examples 18-19 includes, wherein each of the parallel boost branches comprises: a first switch functioning as a current source; a second switch functioning as a synchronization switch; a third switch functioning as a synchronization switch; a fourth switch functioning as a current source; and protection resistors connected in series to protect the synchronization switches.

Example 21 is an apparatus comprising means to implement of any of Examples 1-20.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in fewer than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A system for swing regulation, comprising:
a bias circuit configured for outputting one or more bias currents;
a boost circuit configured for receiving the one or more bias currents and generating one or more boosting currents; and
a voltage mode logic (VML) driver powered by a source voltage, the VML driver configured for receiving the one or more boosting currents and outputting a driver output to drive a load with a swing of the driver output being approximately constant.

2. The system of claim 1, wherein the bias circuit comprises:
a first bias branch formed by a first bias circuit switch and a biasing terminal resistor;
a first operational amplifier (OP1) that has a positive input receiving a voltage that is half of the source voltage and a negative input connected to an OP1 output, the OP1 output coupled to a node in the first bias branch via two series resistors;
a second operational amplifier (OP2) that has a positive input coupled to the OP1 output via one of the two series resistors, a negative input coupled to a reference voltage, and an OP2 output coupled to a gate of the first bias circuit switch;
a first bias output switch that has a source terminal coupled to the source voltage, a gate terminal coupled to the OP2 output, and a drain terminal outputting a first bias current; and
a second bias output switch that has a source terminal coupled to the biasing terminal resistor and a drain terminal outputting a second bias current.

3. The system of claim 2, wherein the bias circuit further comprises:
a second bias branch in parallel to the first bias branch, the second bias branch comprises a second bias circuit switch and a third bias circuit switch, the second bias circuit switch has a source terminal connected to the source voltage and a gate terminal coupled to the OP2 output.

4. The system of claim 2, wherein the VML driver comprises multiple switches forming a bridge circuit with each bridge branch having a pair of switches, the VML driver has a bridge output to drive the load via a termination resistance, the termination resistance has a resistance value same as the biasing terminal resistor.

5. The system of claim 1, wherein the load is a resistive load.

6. The system of claim 1, wherein the bias circuit is configured to adjust the one or more bias currents to track negatively with changes in the source voltage.

7. The system of claim 1, wherein the boost circuit comprises:
a pair of boost branches connected in parallel, each boost branch comprising:
a first switch functioning as a current source;
a second switch functioning as a synchronization switch;
a third switch functioning as a synchronization switch; and
a fourth switch functioning as a current source.

8. The system of claim 7, further comprising protection resistors connected in series within each boost branch to protect the synchronization switches.

9. The system of claim 1, wherein the one or more bias currents comprise:
a first bias current (Iup) connected to a first node between switches in a first boost branch of the boost circuit; and
a second bias current (Idn) connected to a second node between switches in a second boost branch of the boost circuit.

10. The system of claim 1, wherein the VML driver and boost circuit are configured to:
extract a first portion of the swing from the VML driver up to the source voltage level; and
generate a remaining portion of the swing through current boosting.

11. A method for applying current biasing for constant swing in a voltage mode logic (VML) driver, the method comprising:
outputting one or more bias currents to a boost circuit;
supplying one or more boosting currents to a VML driver; and
outputting a driver output to drive a resistive load with a swing of the driver output being approximately constant.

12. The method of claim 11, wherein outputting one or more bias currents comprises:
adjusting the one or more bias currents to track negatively with changes in a source voltage powering the VML driver.

13. The method of claim 11, wherein supplying one or more boosting currents comprises:
generating the one or more boosting currents through a pair of parallel boost branches, each boost branch including synchronization switches and current source switches.

14. The method of claim 13, further comprising:
protecting the synchronization switches using protection resistors connected in series within each boost branch.

15. The method of claim 11, further comprising:
controlling a reference voltage to achieve control of the swing of the driver output.

16. The method of claim 11, further comprising:
extracting a first portion of the swing from the VML driver up to a source voltage level; and
generating a remaining portion of the swing through current boosting.

17. The method of claim 11, wherein outputting one or more bias currents comprises:
supplying a first bias current to a first node between switches in a first boost branch; and
supplying a second bias current to a second node between switches in a second boost branch.

18. A system for regulating voltage mode logic (VML) driver swing, comprising:
a bias circuit including:
a first bias branch formed by a first bias circuit switch and a biasing terminal resistor,
a first operational amplifier having a positive input receiving a voltage that is half of a source voltage, and a negative input connected to an output of the first operational amplifier, and
a second operational amplifier having a positive input coupled to the output of the first operational amplifier, a negative input coupled to a reference voltage, and an output coupled to a gate of the first bias circuit switch;
a boost circuit comprising parallel boost branches configured to receive bias currents from the bias circuit and generate boosting currents; and
a VML driver configured to receive the boosting currents and output a driver signal having an approximately constant swing relative to variations in the source voltage.

19. The system of claim 18, wherein the bias circuit further comprises:
a first bias output switch having a source terminal coupled to the source voltage, a gate terminal coupled to the output of the second operational amplifier, and a drain terminal outputting a first bias current; and
a second bias output switch having a source terminal coupled to the biasing terminal resistor and a drain terminal outputting a second bias current.

20. The system of claim 18, wherein each of the parallel boost branches comprises:
a first switch functioning as a current source;
a second switch functioning as a synchronization switch;
a third switch functioning as a synchronization switch;
a fourth switch functioning as a current source; and
protection resistors connected in series to protect the synchronization switches.
